(19) United States
(12) Patent Application Publication
(10) Pub. No.: US 2025/0022688 A1
(43) Pub. Date: Jan. 16, 2025

(54) PLASMA PROCESSING METHOD AND APPARATUS

(71) Applicant: Tokyo Electron Limited, Tokyo (JP)

(72) Inventor: Barton Lane, Austin, TX (US)

(21) Appl. No.: 18/350,519

(22) Filed: Jul. 11, 2023

(51) Int. Cl. H01J 37/32

(52) U.S. Cl. CPC H01J 37/32449; H01J 37/32201; H01J 2237/334

(57) ABSTRACT

An embodiment plasma processing apparatus includes a plasma generation source, a nozzle in a plasma chamber, the nozzle being able to direct plasma from the plasma generation source to a wafer that is to be processed, the plasma having the form of a plasma stream at an exit of the nozzle, a gas shroud disposed in the plasma chamber and over the wafer, the gas shroud including a first circular opening in a top surface of the gas shroud, a second circular opening in a bottommost surface of the gas shroud, the nozzle being disposed in the first circular opening and the second circular opening, and a gas plenum configured to be maintained at a first pressure, a first region between the second circular opening and a top surface of the wafer being configured to be maintained at a second pressure, the first pressure and the second pressure being different.

### TECHNICAL FIELD

The present invention relates generally to plasma processing, and, in particular embodiments, a plasma processing method and apparatus.

### BACKGROUND

Semiconductor fabrication processes may involve various manufacturing techniques including formation, patterning and removing a number of layers over a substrate. Plasma processes are commonly used in various steps of semiconductor fabrication processes. For example, reactive ion etching (RIE), plasma-enhanced CVD (PECVD) and plasma-enhanced atomic layer deposition (PEALD) are common process steps in the fabrication of semiconductor devices.

Semiconductor wafer die fabrication processes may include film etching processes during pattern transfer. Such processes may be subject to many problems affecting wafer die yield, productivity, reliability, and cost. Such problems can become more prevalent as patterns become smaller and tolerances become more constrained. In plasma fabrication processes, issues can arise due to wafer and film thickness non-uniformity. For example, a wafer may have a smaller thickness towards the center of the wafer than at the edge of the wafer. Therefore, there is a need to be able to controllably etch different regions of the wafer to allow for thickness differences between the different regions of the wafer.

A localized or partial plasma etch can be used to remove material in a first region of a wafer using a plasma, while leaving behind material in other surrounding regions of the wafer. As the plasma processes in the semiconductor industry further advance, there is a need to improve the existing plasma etching processes. These improvements are needed to lower etch damage from unused etch radicals, and reduce contamination from etch by-products and unreacted neutrals to the surrounding regions of the wafer during the localized or partial plasma etch. Improvements are also needed to allow for better control of etching across the surface of the wafer resulting in improved uniformity across the wafer.

### SUMMARY

In accordance with an embodiment, a plasma processing apparatus comprises a plasma generation source, a nozzle in a plasma chamber, the nozzle being able to direct plasma from the plasma generation source to a wafer that is to be processed, the plasma having the form of a plasma stream at an exit of the nozzle, a gas shroud disposed in the plasma chamber and over the wafer, the gas shroud surrounding the nozzle, the gas shroud comprising a first circular opening in a top surface of the gas shroud, a second circular opening in a bottommost surface of the gas shroud, the nozzle being disposed in the first circular opening and the second circular opening, and a gas plenum configured to be maintained at a first pressure, a first region between the second circular opening and a top surface of the wafer being configured to be maintained at a second pressure, the first pressure and the second pressure being different.

In accordance with an embodiment, a method of plasma processing comprises generating a plasma from a plasma source, directing the plasma into a processing chamber and to an outer surface of a wafer using a vertical nozzle, the plasma exiting at an end of the vertical nozzle disposed above the outer surface of the wafer, the plasma exiting in the form of a plasma stream, the vertical nozzle extending through a gas shroud that surrounds the vertical nozzle and that is disposed over the wafer, the plasma stream being disposed in a first region that comprises a space between an opening in a bottommost surface of the gas shroud and the outer surface of the wafer, supplying an inert gas to a gas plenum of the gas shroud to maintain a first pressure in the gas plenum, and distributing the inert gas from the gas plenum to the first region to maintain a second pressure in the first region, the first pressure being higher than the second pressure.

In accordance with an embodiment, an apparatus comprises a radical source, a nozzle configured to deliver radicals from the radical source into a processing chamber, a gas shroud disposed over a wafer to be processed in the processing chamber, the gas shroud comprising a first opening in a topmost surface of the gas shroud, a second opening in a bottommost surface of the gas shroud, a first region being disposed between the second opening and a top surface of the wafer, a gas plenum, and first orifices arranged in the form of a ring pattern around the second opening, the first orifices acting as a conduit for gas flow between the gas plenum and the first region, an exit of the nozzle being disposed in the first region and being above the wafer, the nozzle extending through the first opening, the second opening, and the gas shroud.

The foregoing has outlined rather broadly the features and technical advantages of the present disclosure in order that the detailed description of the disclosure that follows may be better understood. Additional features and advantages of the disclosure will be described herein, which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a block diagram of a plasma processing system, in accordance with various embodiments of the present disclosure;

FIG. 2 illustrates a cross-sectional view of a gas shroud of the plasma processing system shown in FIG. 1, in accordance with various embodiments of the present disclosure;

FIGS. 3A and 3B illustrate cross-sectional views of the gas shroud shown in FIG. 2 during an etching process, in accordance with various embodiments of the present disclosure;

FIG. 4A illustrates a top-down view of a plasma processing tool, in accordance with various embodiments of the present disclosure;

FIG. 4B illustrates a cross-sectional view of a gas shroud shown in FIG. 4A during an etching process, in accordance with various embodiments of the present disclosure; and

FIG. 5 illustrates a flow chart of a method applied using the plasma processing system and the plasma processing tool shown in FIGS. 1 through 4B, in accordance with various embodiments of the present disclosure;

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The present disclosure will be described with respect to preferred embodiments in a specific context, namely an apparatus and method for localized or partial plasma etching that includes a nozzle that directs plasma and radicals from a plasma source towards a wafer to be etched. The plasma and radicals are directed in the form of a plasma stream (also referred to subsequently as a plume) at the nozzle exit. The wafer to be etched and the nozzle exit are in a plasma chamber. The apparatus and method also include a gas shroud that is used to create sonic flow (e.g., using jets of an inert gas traveling at a speed equal to the speed of sound) in a first region between a base of the gas shroud and a top surface of the wafer being etched. The nozzle is installed within the shroud. The sonic flow can be used to control pressure in the first region, and allows for a pressure differential to be maintained between the first region and other regions within the plasma chamber. A lateral width of the plasma plume at the nozzle exit is dependent on the pressure in the first region, and since the pressure in the first region is dependent on the flowrate of the sonic flow of the gas shroud, design selection of the appropriate gas shroud can be used to control the lateral width of the plasma plume. The lateral width is a width between outermost points of the plasma plume that are in physical contact with a top surface of the wafer. The plasma plume can be focused on a smaller area of the wafer surface (e.g., the plasma plume has a smaller etch spot size) directly under the nozzle, and the amount of material to be etched from the wafer can be controlled. The sonic flow from the gas shroud directs etch by-products, unused radicals, and unreacted neutrals from the plasma up through the shroud and out of the plasma chamber. In addition, the sonic flow separates the first region from surrounding regions and prevents the etch by-products, the unused radicals, and the unreacted neutrals from coming into contact with surfaces of the wafer in these surrounding regions that we do not wish to etch.

Advantages can be achieved by using the gas shroud to create the sonic flow in the first region in order to maintain a pressure in the first region. This includes the ability to control a lateral width of the plasma plume, which results in better etch control, improved focusing of the plasma plume, and better etch spot size control. This will therefore allow for high-resolution etching and result in better uniformity across the surface of the wafer. Further advantages are achieved by the sonic flow directing etch by-products, the unused radicals, and the unreacted neutrals from the plasma up through the shroud and out of the plasma chamber, and by the sonic flow separating the first region from the surrounding regions to prevent the etch by-products, the unused radicals, and the unreacted neutrals from coming into contact with surfaces of the wafer in these surrounding regions. These include reduced unintended etch damage from the unused etch radicals, and reduced contamination from the etch by-products and the unreacted neutrals to the surrounding regions of the wafer during the partial plasma etch. Hereinafter, various embodiments will be explained in detail with reference to the accompanying drawings.

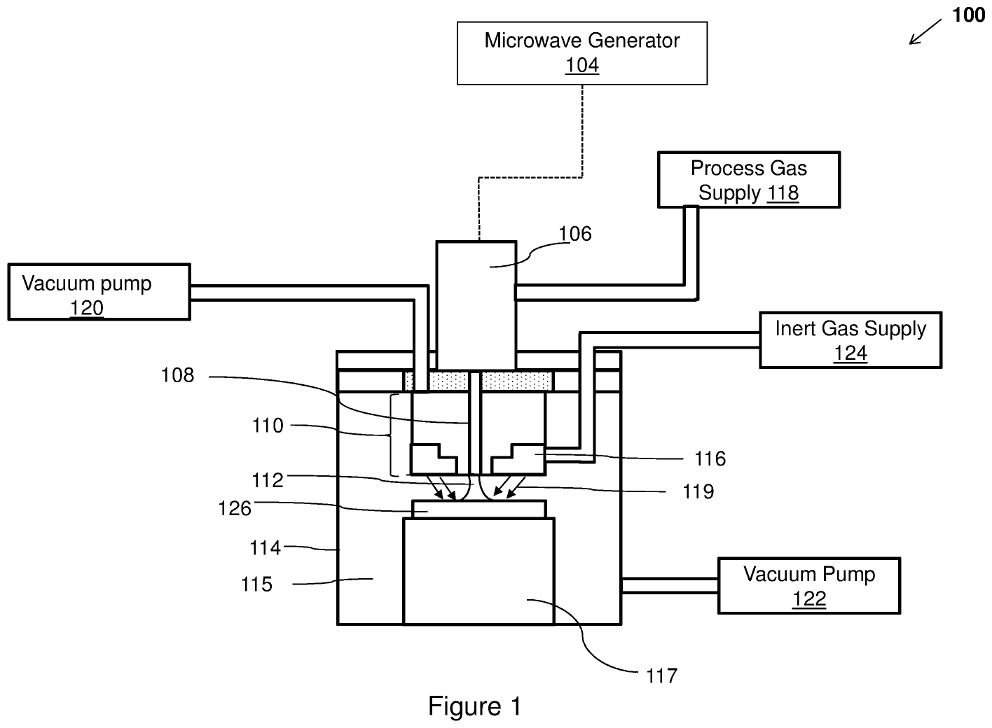

FIG. 1 illustrates a schematic cross-sectional view of an example of a plasma processing system 100 in accordance with the technology described herein. Depending upon the implementation, the plasma processing system 100 may be a capacitively coupled plasma (CCP) processing system, inductively coupled plasma (ICP) processing system, microwave-generated plasma system, or the like. The example plasma processing system 100 is described subsequently for use in the context of etching operations. However, aspects of the embodiments described herein may be used for other plasma operations including ashing, deposition, cleaning, plasma polymerization, plasma-enhanced chemical vapor deposition (PECVD), plasma-enhanced atomic layer deposition (PEALD) and so forth. Plasma processing can be executed within a plasma processing chamber 114, which can be a vacuum chamber made of a metal such as aluminum, stainless steel, or the like.

The microwave generator 104 generates electromagnetic waves (microwaves) that are distributed to a plasma source 106 in which plasma is generated. In other embodiments, the source of the electromagnetic waves may have a frequency that is in a range from the 10's of MHz (e.g., Radio-Frequency (RF)) to 1-30 GHz (microwave). The plasma source 106 is disposed above the plasma processing chamber 114, and may comprise a plasma cavity and a plasma element that is used to produce plasma in the plasma cavity. In an embodiment, the plasma source 106 may be a remote plasma source that is disposed in a different location, with the plasma being directed to a surface to be etched after being generated. The plasma element may produce a mixture of plasma and radicals which then flows into the plasma processing chamber 114 through a nozzle 108. The plasma is therefore generated outside of the plasma processing chamber 114 and then introduced into the plasma processing chamber using a gas flow.

A process gas is introduced into the plasma cavity of the plasma source 106, where it is ionized and excited by the plasma. This gas may be a mixture of one or more reactive gases, such as oxygen, nitrogen, hydrogen, fluorine, or the like, depending on the specific process being performed. In an embodiment, the process gas may be a fluorine-rich precursor, such as NF₃, SF₆, or the like. The process gas is supplied using a process gas supply 118, and is introduced into the plasma cavity through a gas inlet. The process gas may be mixed with a carrier gas, such as argon or helium, to ensure uniform distribution and stable plasma operation. The gas mixture is then energized by the plasma, which dissociates the gas molecules into reactive species such as radicals, ions, or excited molecules.

The plasma and radicals generated in the plasma source 106 then flow into the plasma processing chamber 114 through the vertical nozzle 108, and an exit of the nozzle 108 is positioned over a wafer support 117 (e.g., a wafer chuck, or the like) in the plasma processing chamber 114. The wafer support 117 is configured to hold a wafer 126 (or for example, a substrate, or the like) to be etched, so that the radicals and plasma are ejected from the exit of the nozzle 108 towards a top surface of the wafer 126. The plasma and radicals are directed towards the top surface of the wafer 126 in the form of a plasma plume 112 (also referred to as a plasma stream) at the exit of the nozzle 108. The plasma plume 112 comprises a narrow column or stream of plasma and radicals. However, as the plasma plume 112 travels away from the exit of the nozzle 108 (e.g., in a vertically downward direction), the plasma plume 112 has a tendency to widen or diverge, and spread out over a larger area as it encounters the wafer 126 below. It is desirable for the plasma plume 112 to be more focused on a smaller area of the wafer 126 surface (e.g., the plasma plume 112 has a smaller etch spot size) such that the amount of material to be etched from the wafer 126 during an etching process can be controlled.

The plasma processing system 100 may comprise a gas shroud 110 that is used to control a lateral width of the plasma plume 112, and allow for the focusing of the plasma plume 112 on a smaller area of the wafer 126 surface (e.g., by reducing a lateral width of the plasma plume 112). The lateral width may be a width between outermost points of the plasma plume 112 that are in physical contact with a top surface of the wafer 126. The gas shroud 110 is disposed in the plasma processing chamber 114, over the wafer support 117 and the wafer 126. The gas shroud 110 has a circular shape when viewed in a top-down view, and has a first opening in a topmost surface of the gas shroud 110, and a second opening in a bottommost surface of the gas shroud 110. The first opening has a circular shape and is disposed at a center of a top surface of the gas shroud 110 when viewed in a top-down view. The cylindrical nozzle 108 is disposed to be fitted through the first opening and the second opening, such that the gas shroud 110 surrounds vertical sidewalls of the nozzle 108, and a fit between the nozzle 108 and a top surface of the gas shroud 110 is sealed to gas.

The gas shroud 110 comprises a gas plenum 116 that is designed to create an inward sonic flow 119 (e.g., formed by jets of inert gas that flow at a speed equal to the speed of sound) in a first region between a base of the gas shroud 110 and the wafer 126. The plasma plume 112 and the exit of the nozzle 108 are disposed within this first region. The sonic flow 119 of the gas shroud 110 can be used to maintain a pressure within the first region, and since the lateral width of the plasma plume 112 is dependent on the pressure within the first region, the lateral width of the plasma plume 112 can be controlled. The sonic flow is created from an inert gas supplied to the gas plenum 116 by the inert gas supply 124. The inert gas may comprise argon, nitrogen, or the like. The gas plenum 116 then evenly distributes this inert gas into the first region through a series of small orifices or channels in the base of the gas shroud 110 to form the sonic flow 119. A vacuum pump 120 is connected to the gas shroud 110 and is used to remove etch by-products, unused radicals, and unreacted neutrals from the plasma plume 112 up through the gas shroud 110 and out of the plasma processing chamber 114 through a gas outlet.

During an etching process using the plasma processing system 100, the wafer 126 can moved or scanned under the plasma plume 112 in order to etch material from the wafer 126. Alternatively, the combination of the nozzle 108 and the gas shroud 110 can be scanned across a surface of the wafer 126 during the etching process. The wafer scan speed and dwell time during the etching process can be controlled to control uniformity across the wafer 126, and to allow for uniform etching across the entire surface of the wafer 126.

A vacuum pump 122 is connected to the plasma processing chamber 114 through a gas outlet, and the vacuum pump 122 helps to maintain a desired pressure in regions 115 of the plasma processing chamber 114.

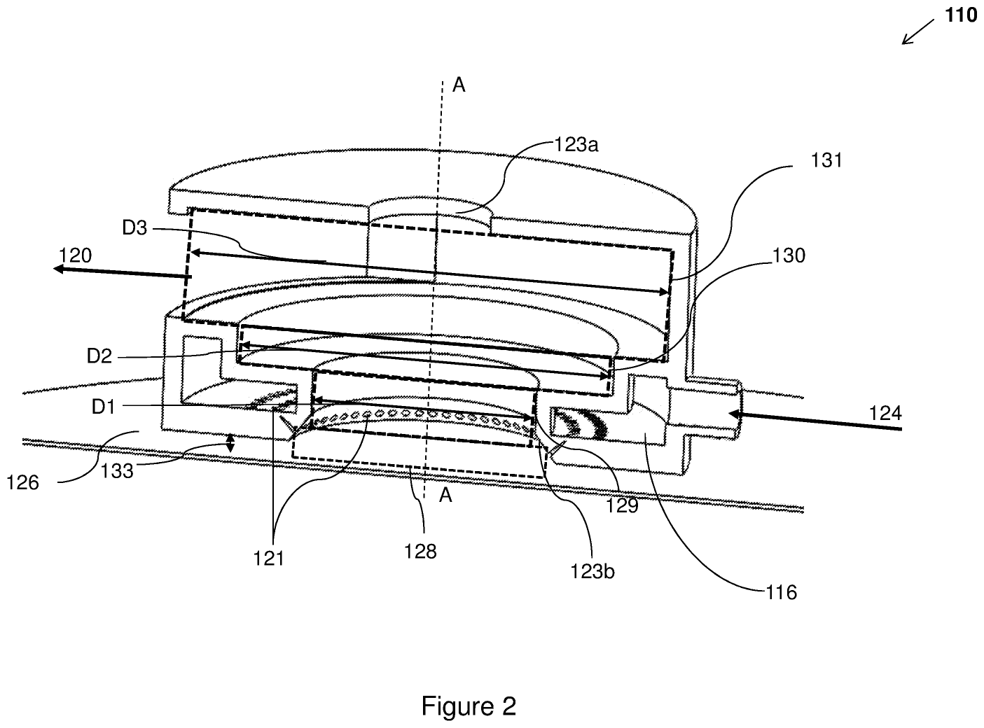

FIG. 2 shows a cross-sectional view of the gas shroud 110. The gas shroud 110 is shown as being disposed over the wafer 126. Specifically, the gas shroud is disposed to be over an area of the wafer 126 that is to be etched. The gas shroud 110 may comprise a material such as alumina (Al₂O₃), aluminum or the like. In some embodiments, the gas shroud comprises a material that is resistant to the etchants of the specific etching process being performed. It should be noted that even though the gas shroud 110 and the nozzle 108 are described as being used in context of an etching process, the embodiments described herein (including the gas shroud 110 and nozzle 108) may be used in the context of other types of plasma operations. These operations include ashing, deposition, cleaning, plasma polymerization, plasma-enhanced chemical vapor deposition (PECVD), plasma-enhanced atomic layer deposition (PEALD) and so forth.

As illustrated, in various embodiments, the gas shroud 110 has a circular shape in a top-down view, and has a circular opening 123a on a topmost surface of the gas shroud 110 and a circular opening 123b at a bottommost surface of the gas shroud 110. The opening 123b may have a larger diameter than the opening 123a, and the opening 123a may overlap and be connected to the opening 123b. In a top-down view, the opening 123a is disposed at a center of a top surface of the gas shroud 110. The nozzle 108 (described previously in FIG. 1) may have a cylindrical shape and can be installed into the opening 123a and the opening 123b in the gas shroud 110 such that the gas shroud 110 surrounds vertical sidewalls of the nozzle 108, and a fit between the nozzle 108 and a top surface of the gas shroud 110 is sealed to gas. As such, the nozzle 108 may extend into the openings 123a and 123b and through the gas shroud 110. The nozzle 108 may comprise alumina (Al₂O₃), or the like. The gas shroud 110 comprises an enclosed space that has inter-connected sections of different sizes. For example, the gas shroud 110 may comprise a first section 129, a second section 130, and a third section 131 that are arranged in a concentric manner, where the third section 131 is disposed over the second section 130, and the second section 130 is disposed over the first section 129. Gases may flow from one of these sections (e.g., the first section 129, the second section 130, or the third section 131) to other sections, and the direction of flow and the rate of gas flow will depend on the pressure difference between the sections.

Each of the first section 129, the second section 130, and the third section 131 comprise an annular (e.g., a ring-shaped structure with space in the middle) structure. The first section 129 has a first internal diameter D1 between first inner sidewalls of the first section 129. The second section 130 has a second internal diameter D2 between second inner sidewalls of the second section 130. The third section 131 has a third internal diameter D3 between third inner sidewalls of the third section 131. In an embodiment, third internal diameter D3 is larger than the second internal diameter D2, and the second internal diameter D2 is larger than the first internal diameter D1.

The opening 123b of the gas shroud 110 is disposed to be vertically below the first section 129. The opening 123b comprises a first space that is disposed between sidewalls of a base of the gas shroud 110. A first region 128 comprises a combination of the first space of the opening 123b, and a second space disposed vertically below and overlapped by the opening 123b, the second space being between the opening 123b and a top surface of the wafer 126.

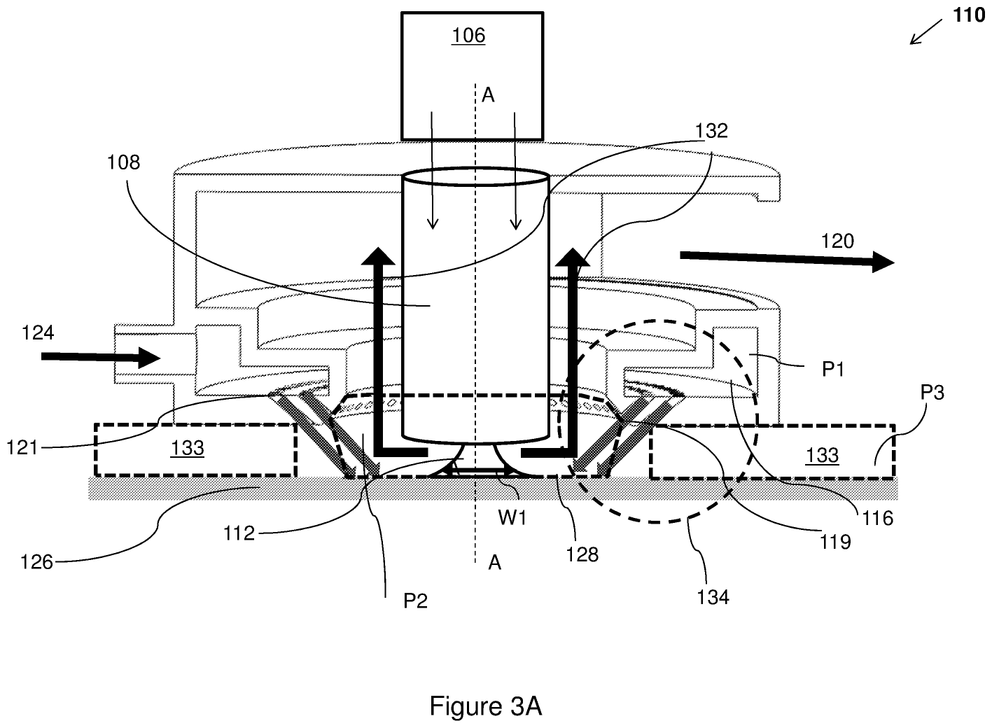

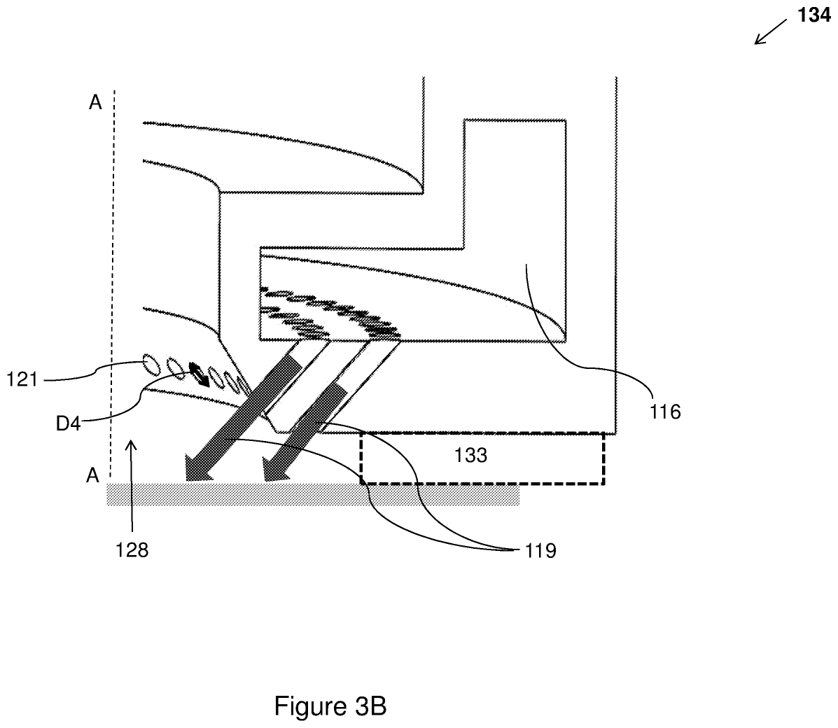

The nozzle 108 (shown in FIGS. 1 and 3A) may be installed to be disposed within the gas shroud 110, in the opening 123a and the opening 123b. The axis (also referred to subsequently as the length) of the nozzle 108 may extend completely through the third section 131, the second section 130, and the first section 129. In an embodiment, the axis of the nozzle 108 extends completely through the third section 131 and the second section 130, and extends only partially through the first section 129. In an embodiment, the axis of the nozzle 108 extends completely through the third section 131, the second section 130, and the first section 129, and extends only partially through the first region 128. The exit of the nozzle 108 is disposed above a surface of the wafer 126 in the first region 128. During an etching process to etch material from the wafer 126 in the first region 128, radicals and plasma are ejected from the exit of the nozzle 108 in the form of the plasma plume 112 (described previously in FIG. 1) towards the top surface of the wafer 126 in the first region 128. The plasma plume 112 travels away from the exit of the nozzle 108 (e.g., in a vertically downward direction) and through the first region 128, until it encounters the top surface of the wafer 126 that is to be etched.

The gas shroud 110 also comprises a gas plenum 116. The gas plenum 116 is a volume or chamber that surrounds the first section 129 along the perimeter of the first section 129. There is no direct connection or passage for gas to flow between the gas plenum 116 and the first section 129. In an embodiment, the gas plenum 116 also surrounds a lower portion of the second section 130 along the perimeter of the second section 130. There is no direct connection or passage for gas to flow between the gas plenum 116 and the second section 130. The gas plenum 116 is used to create an inward sonic flow 119 (shown in FIG. 1 and FIG. 3A) in the first region 128. The sonic flow 119 is formed by distributing an inert gas uniformly from the gas plenum 116 to the first region 128 through a series of small orifices 121 (shown in FIGS. 2 and 3B) in the base of the gas shroud 110. The orifices 121 may also be referred to subsequently as channels. In an embodiment, the orifices 121 are arranged in the form of a ring pattern in the base of the gas shroud 110, where the ring pattern is disposed around the opening 123b. In an embodiment, the gas shroud 110 may comprise multiple rings of orifices 121 in the base of the gas shroud 110. In an embodiment, at least one ring of the multiple rings of orifices 121 is disposed in sidewalls of the opening 123b. The multiple rings of orifices 21 may be arranged in a concentric pattern, with each ring having a different diameter from diameters of the other rings.

The orifices 121 directly connect and allow gas flow (e.g., as a conduit or passage) from the gas plenum 116 to flow into the first region 128. The orifices 121 may be distributed evenly around the perimeter of the first region 128 and each orifice 121 may have a diameter D4 (shown in FIG. 3B) that may be in a range from 0.3 mm to 2.0 mm. In an embodiment, any number and placement of orifices 121 may be used to create the sonic flow 119.

The gas plenum 116 is maintained at a much higher pressure than the first region 128, and due to this pressure differential, and due to the orifices 121 having a diameter D4 in a range from 0.3 mm to 2.0 mm, the inert gas is forced through the orifices 121 into the first region 128 at a speed that is equivalent to the speed of sound (also referred to as sonic flow 119). The placement of the orifices 121 directs the sonic flow 119 (e.g. in the form of jets of inert gas from each orifice 121) towards a surface of the wafer 126 at an angle, as well as towards the plasma plume 112 (e.g., inward sonic flow). For example, the orifices 121 are angled such that topmost portions of the sonic flow 119 may be further away form a vertical line A-A which passes through the center of the first region 128 than bottommost portions of the sonic flow 119 that encounter a top surface of the wafer 126. In this way, inward sonic flow 119 can be created that completely surrounds the plasma plume 112 in the first region 128, and isolates the plasma plume 112 and first region 128 from second regions 133. The second regions 133 are regions that are adjacent to and surround the first region 128, the second regions 133 comprising spaces between the base of the gas shroud 110 and top surfaces of the wafer 126. In addition, the inward sonic flow 119 isolates the plasma plume 112 and first region 128 from other regions of the plasma processing chamber 114.

The inert gas that is supplied to the gas plenum 116 is supplied through a gas inlet of the gas plenum 116. The inert gas is supplied at high pressure by the inert gas supply 124, and the inert gas may comprise argon, nitrogen, or the like.

Gases may flow from the first region 128 to any of the sections (e.g., the first section 129, the second section 130, or the third section 131) of the gas shroud 110, and the direction of flow and the rate of gas flow will depend on the pressure difference between the sections. During an etching process, etch by-products, unused radicals, unreacted neutrals, and the inert gas used to create the sonic flow 119 are removed up through the gas shroud 110 and out of the gas shroud 110 through a gas outlet connected to vacuum pump 120. The vacuum pump 120 maintains the first section 129, the second section 130 and the third section 131 at a lower pressure than the first region 128 and hence the flow path for the etch by-products, unused radicals, unreacted neutrals, and the inert gas used to create the sonic flow 119 may include the etch by-products, the unused radicals, the unreacted neutrals, and the inert gas travelling vertically upward from the first region 128, through the first section 129, the second section 130, and into the third section 131. The third section 131 may comprise the gas outlet that is connected to the vacuum pump 120. The etch by-products, the unused radicals, the unreacted neutrals, and the inert gas are evacuated from the gas shroud 110 though this gas outlet.

FIGS. 3A and 3B show a cross-sectional view of the gas shroud 110 during an etching process to etch material from a top surface of the wafer 126 in the first region 128. FIG. 3B shows a region 134 of the gas shroud 110 that is illustrated in FIG. 3A. The plasma and radicals generated in the plasma source 106 flow into the plasma processing chamber 114 through the nozzle 108. The radicals and plasma are ejected from the exit of the nozzle 108, and travel through the first region 128 towards a top surface of the wafer 126 in the form of the plasma plume 112. The radicals in the plasma plume 112 are used to etch material of the wafer 126 in the first region 128.

An inert gas is supplied to the gas plenum 116 under high pressure through a gas inlet of the gas plenum 116. The inert gas may comprise argon, nitrogen, or the like, and may be supplied by the inert gas supply 124. The inert gas is supplied to the gas plenum 116 under high pressure, such that there is a large pressure differential between the gas plenum 116 and the first region 128. A pressure P1 in the gas plenum 116 is maintained to be much larger than a pressure P2 in the first region 128. The pressure P1 is maintained by supplying the inert gas through the gas inlet of the gas plenum 116. For example the pressure P1 may be in a range from 1 torr to 50 torr, and the pressure P2 may be in a range from 0.1 torr to 5 torr. Each orifice 121 that allows passage of the inert gas from the gas plenum 116 into the first region 128 has a diameter D4 that is in a range from 0.3 mm to 2.0 mm. Because of the pressure differential between the first region 128 and the gas plenum 116, and because each of the orifices 121 has a relatively small diameter D4 that is in a range from 0.3 mm to 2.0 mm, the inert gas is forced through the orifices 121 into the first region 128 at a speed that is equivalent to the speed of sound (e.g., the sonic flow 119). The pressure P2 in the first region 128 can be maintained using the sonic flow 119 coming into the first region 128 from the gas plenum 116. The flowrate of the sonic flow 119 may influence the pressure P2 that can be maintained. For example, a gas shroud 110 having more orifices 121 would have a higher flowrate of the inert gas flowing into the first region 128, and hence a higher pressure P2 could be maintained. A gas shroud 110 having fewer orifices 121 would have a lower flowrate of the inert gas flowing into the first region 128, and hence it would only be possible to maintain a lower pressure P2.

Jets of the inert gas (also referred to as sonic flow 119) flow at a speed that is equivalent to the speed of sound into the first region 128 from the orifices 121. The sonic flow 119 flows towards a surface of the wafer 126 at an angle. The sonic flow 119 also flows in such a way that it moves a lateral distance towards the plasma plume 112 (also referred to as inward sonic flow 119). For example, as shown in FIG. 3A, topmost portions of the sonic flow 119 may be further away form a vertical line A-A which passes through the center of the first region 128 and the nozzle 108 than bottommost portions of the sonic flow 119 that encounter a top surface of the wafer 126. In this way, inward sonic flow 119 can be created that completely surrounds the plasma plume 112, and isolates the plasma plume 112 and the first region 128 from second regions 133. The second regions 133 are regions that are adjacent to and surround the first region 128, the second regions 133 comprising spaces between the base of the gas shroud 110 and top surfaces of the wafer 126. In addition, the inward sonic flow 119 isolates the plasma plume 112 and the first region 128 from other regions of the plasma processing chamber 114. The sonic flow 119 acts as a separatrix (also referred to as a boundary) between the first region 128 and the second regions 133. For example, the first region 128 and the second regions 133 have distinct flows that are kept separate from each other by the sonic flow 119. In this way the first region 128 may have and be maintained at a different pressure than the second regions 133.

Forming the sonic flow 119 that comprises jets of inert gas that flow into the first region 128 and surround the plasma plume 112 allows for maintaining a pressure differential between the pressure P2 in the first region 128 and a pressure P3 in the second regions 133. In addition, forming the sonic flow 119 that comprises jets of inert gas that flow into the first region 128 and surround the plasma plume 112 allows for maintaining a pressure differential between the pressure P2 in the first region 128 and a pressure in other regions of the plasma processing chamber 114. The pressure in the other regions of the plasma processing chamber 114 may be equal to the pressure P3. The pressure P3 may be greater than the pressure P2. In an embodiment, the pressure P3 may be in a range from 0.1 torr to 10 torr.

Advantages can be achieved by forming the inward sonic flow 119 that completely surrounds the plasma plume 112, and the sonic flow 119 forming a separatrix to isolate the plasma plume 112 and the first region 128 from the second regions 133. The separatrix prevents the etch by-products, the unused radicals, and the unreacted neutrals that result from the etching process from traveling or diffusing to the second regions 133 from the first region 128. They therefore do not come into contact with surfaces of the wafer 126 in the second regions 133. This results in reduced unwanted etching from the unused etch radicals, and reduced contamination from the etch by-products and the unreacted neutrals to portions of the wafer 126 in the second regions 133. If the jets of inert gas coming from the orifices 121 were to travel at a speed that is lower than the speed of sound, no separatrix would be formed between the first region 128 and the second regions 133, and it would not be possible to maintain a pressure differential between the pressure P2 in the first region 128 and a pressure P3 in the second regions 133.

Gases may flow from the first region 128 to any of the sections (e.g., the first section 129, the second section 130, or the third section 131) of the gas shroud 110, and the direction of flow and the rate of gas flow will depend on the pressure difference between the sections. As described above, due to the sonic flow 119, the pressure P2 can be maintained in the first region 128. The vacuum pump 120 maintains the first section 129, the second section 130 and the third section 131 of the gas shroud 110 at a lower pressure than the first region 128. As a result, etch by-products, unused radicals, unreacted neutrals from the etching process, and the inert gas used to create the sonic flow 119 travel from the higher pressure first region 128 to the lower pressure first section 129, the second section 130, and the third section 131. The etch by-products, the unused radicals, unreacted neutrals, and the inert gas used to create the sonic flow 119 are removed up through the gas shroud 110 and out through a gas outlet of the gas shroud 110 that is connected to the vacuum pump 120. In an embodiment, more than one gas outlet and one or more vacuum pumps 120 may be connected to the gas shroud 110 to allow for different pumping capacities. Advantages can be achieved by using the sonic flow 119 to maintain the pressure P2 in the first region 128 to be higher than the pressure in the first section 129, the second section 130 and the third section 131 of the gas shroud 110. This allows the etch by-products, the unused radicals, and the unreacted neutrals that result from the etching process to be removed up through the gas shroud 110 and out through the gas outlet of the gas shroud 110 that is connected to the vacuum pump 120. As a result, the etch by-products, the unused radicals, and the unreacted neutrals have reduced contact with surfaces of the wafer 126 in the second regions 133. This results in reduced etch damage from the unused etch radicals, and reduced contamination from the etch by-products and the unreacted neutrals to portions of the wafer 126 in the second regions 133.

As described above, forming the sonic flow 119 that comprises jets of inert gas that flow into the first region 128 and surround the plasma plume 112 allows for maintaining a pressure differential between the pressure P2 in the first region 128 and a pressure P3 in the second regions 133. In addition, forming the sonic flow 119 that comprises jets of inert gas that flow into the first region 128 and surround the plasma plume 112 allows for maintaining a pressure differential between the pressure P2 in the first region 128 and a pressure in other regions of the plasma processing chamber 114. The plasma plume 112 may have a lateral width W1, where the lateral width W1 is a width between outermost points of the plasma plume 112 that are in physical contact with a top surface of the wafer 126. The lateral width W1 is dependent on the pressure P2 in the first region 128, such that a higher pressure P2 results in a reduced lateral width W1 of the plasma plume 112. A lower pressure P2 results in a larger lateral width W1 of the plasma plume 112. Design selection of the appropriate gas shroud 110 and its corresponding sonic flow 119 can be used to control the lateral width W1 of the plasma plume 112. In an embodiment, the lateral width W1 of the plasma plume 112 may be in a range from 2 mm to 20 mm.

The flowrate of the sonic flow 119 may influence the pressure P2 that can be maintained. For example, a gas shroud 110 having more orifices 121 would have a higher flowrate of the inert gas flowing into the first region 128, and hence a higher pressure P2 could be maintained. A gas shroud 110 having fewer orifices 121 would have a lower flowrate of the inert gas flowing into the first region 128, and hence it would only be possible to maintain a lower pressure P2.

Advantages can be achieved by using the gas shroud 110 to create the sonic flow 119 in the first region 128 in order to maintain the pressure P2 in the first region 128. For example, design selection of a gas shroud 110 having a larger number of orifices 121 would increase the flowrate of the sonic flow 119 into the first region 128, and allow the maintaining of a higher pressure P2 in the first region 128. This would result in a decrease in the lateral width W1 of the plasma plume 112. Design selection of a gas shroud 110 having a smaller number of orifices 121 would decrease the flowrate of the sonic flow 119 into the first region 128, and allow the maintaining of a lower pressure P2 in the first region 128. This would result in an increase in the lateral width W1 of the plasma plume 112. Being able to control the lateral width W1 of the plasma plume 112 in this manner allows for better etch control, improved focusing of the plasma plume 112, and better etch spot size control, which allows for high-resolution etching and results in better uniformity across the surface of the wafer 126. In addition, it is more convenient and easier to maintain the pressure P2 in the first region 128 during plasma processing, than to maintain the pressure in the entire plasma processing chamber 114. This is because a volume of the first region 128 is much smaller than a volume of the plasma processing chamber 114. For example, by changing the flow of the inert gas that is supplied to the gas plenum 116, the pressure P2 in the first region 128 can be adjusted in a dynamic fashion, allowing more dynamic control of the lateral width W1 of the plasma plume 112. Conversely, changing a pressure of the entire plasma processing chamber 114 would take much longer to do since the volume of the plasma processing chamber 114 is larger than the volume of the first region 128.

In an alternate embodiment, the inert gas supplied to the gas plenum 116 under high pressure may be forced through the orifices 121 into the first region 128 at a speed that is lower than the speed of sound (e.g., in a range between 90 percent to 99 percent the speed of sound). Jets of the inert gas (also referred to as sub-sonic flow) may flow at a speed that is lower than the speed of sound into the first region 128 from the orifices 121. The sub-sonic flow may flow towards a surface of the wafer 126 at an angle. The sub-sonic flow also flows in such a way that it moves a lateral distance towards the plasma plume 112. In this way, the sub-sonic flow can be created that completely surrounds the plasma plume 112.

The vacuum pump 120 maintains the first section 129, the second section 130 and the third section 131 of the gas shroud 110 at a lower pressure than the first region 128 and other regions of the plasma processing chamber 114. The sub-sonic flow results in an increase in the pressure in the first region 128 and forces bulk flow up towards the vacuum pump 120. The sub-sonic flow may push and confine etch by-products, unused radicals and unreacted neutrals from the etching process to the first region 128, and prevent them from travelling to the second regions 133. By being confined and pushed to the first region 128, an increased amount of the etch by-products, the unused radicals and the unreacted neutrals may be removed from the gas outlet of the gas shroud 110 through the first section 129, the second section 130 and the third section 131. Advantages can be achieved by using sub-sonic flow to push and confine the etch by-products, the unused radicals and the unreacted neutrals from the etching process to the first region 128, and prevent them from travelling to the second regions 133. These include increasing the amount of the etch by-products, the unused radicals, and the unreacted neutrals that result from the etching process being removed up from the first region 128, through the gas shroud 110 and out through the gas outlet of the gas shroud 110 that is connected to the vacuum pump 120. As a result, the etch by-products, the unused radicals, and the unreacted neutrals have reduced contact with surfaces of the wafer 126 in the second regions 133. This results in reduced etch damage from unused etch radicals, and reduced contamination from etch by-products and unreacted neutrals to portions of the wafer 126 in the second regions 133.

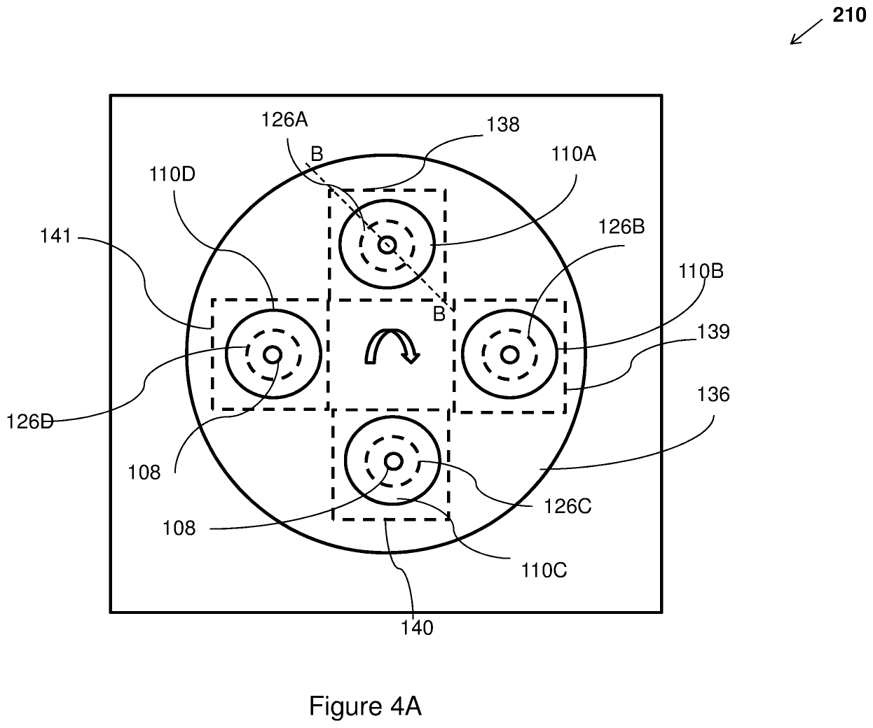

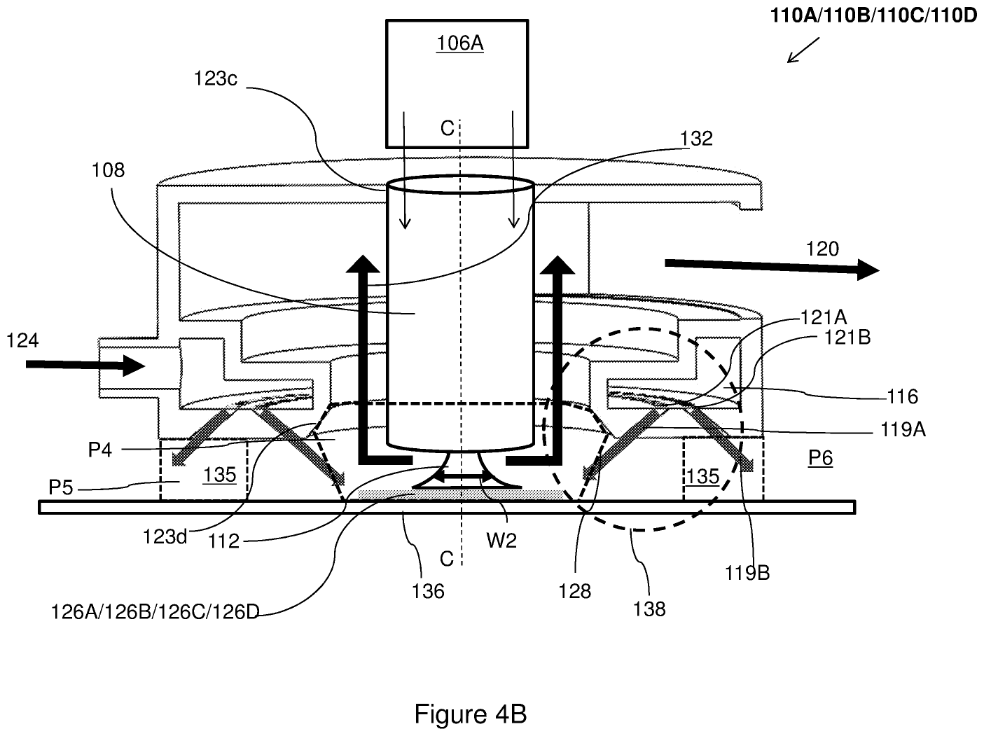

FIG. 4A illustrates a top-down view of an example plasma processing tool 210, in accordance with some embodiments. The plasma processing tool 210 includes features described previously in the FIGS. 1 through 3B, as well as additional features to provide further advantages. Unless specified otherwise, like reference numerals discussed in FIGS. 4A and 4B represent like components described and shown previously in FIGS. 1 through 3B, and formed by like processes. Accordingly, the process steps and applicable materials may not be repeated herein. The example plasma processing tool 210 in FIG. 4A is described subsequently for use in the context of etching operations. However, aspects of the embodiments described herein may be used for other plasma operations including ashing, deposition, cleaning, plasma polymerization, plasma-enhanced chemical vapor deposition (PECVD), plasma-enhanced atomic layer deposition (PEALD) and so forth. In particular, the plasma processing tool 210 may be used to perform a plurality of processes, and these processes can be either etch or deposition processes that utilize sequential etch and/or deposition steps to enable atomic layer deposition (ALD) or atomic layer etching (ALE) or a combination of the two to enable area selective etch or deposition.

The example plasma processing tool 210, according to embodiments disclosed herein, may be used to perform a plurality of etching processes (e.g., etching process 138, etching process, 139, etching process 140, and etching process 141). Any number of different etching processes may be performed by the plasma processing tool 210.

The plasma processing tool 210 shown in FIG. 4A may comprise a rotatable susceptor 136 (also referred to as a platen) in a processing chamber. The susceptor 136 may comprise a number of vacuum or electrostatic chucks disposed around a center of the susceptor 136 to enable the holding or retaining in place of a plurality of wafers 126 against a top surface of the susceptor 136. The vacuum or electrostatic chucks may be equidistantly disposed from each other on the susceptor 136. In FIG. 4A, four wafers 126 (e.g., wafer 126A, wafer 126B, wafer 126C, and wafer 126D) are illustrated being held against the top surface of the susceptor 136 using vacuum chucks for processing. However, any number of wafers 126 can be held or supported by the susceptor 136 for processing. In FIG. 4A, the wafers 126 are shown in ghost.

The plasma processing tool 210 may comprise load ports (not shown in the Figures), and a handler (not shown in the Figures). The load ports may be used for loading the wafers 126 into the plasma processing tool 210, and then unloading the wafers 126 once the plasma processing has been completed. The handler may be used to transfer each wafer 126 to a prescribed position on the susceptor 136, where it is held or retained against the top surface of the susceptor 136 by a respective vacuum or electrostatic chuck. The handler may comprise a robotic machine, an automated machine, or a transfer robot that is adapted to mechanically position and manipulate the wafers 126 within the plasma processing tool 210 during processing. FIG. 4A shows four wafers 126 being held or retained on the top surface of the susceptor 136 using vacuum or electrostatic chucks. Each wafer 126 (e.g., the wafer 126A, the wafer 126B, the wafer 126C, and the wafer 126D) is disposed to be under a respective gas shroud 110 (e.g., gas shroud 110A, gas shroud 110B, gas shroud 110C, and gas shroud 110D) and respective nozzle 108 of the plasma processing tool 210. Each wafer 126 that is under a respective gas shroud 110 and respective nozzle 108 may be subjected to a plasma etching process using a plasma plume 112 at the respective nozzle 108 exit in a similar manner as described previously in FIGS. 1 through 3B. The etching process each wafer 126 is subjected to may be a different etching process than the etching processes that the other wafers 126 are subjected to, wherein the etching process uses different etchants than the etchants of the other etching processes.

Each gas shroud 110 and its respective nozzle 108 can be configured to facilitate a plasma etch process that is different (e.g., by using different etchants) than plasma etch processes that are facilitated by the other gas shrouds 110 and their respective nozzles 108. To perform an etching process, the susceptor 136 is rotated to dispose a wafer 126 under a gas shroud 110 and its respective nozzle 108, after which the etching process is performed. In an embodiment, different wafers 126 can be etched concurrently in the plasma processing tool 210 using different etching processes while being disposed under different gas shrouds 110 and their respective nozzles 108. In addition, the susceptor 136 can also be rotated so that a single wafer 126 can sequentially undergo different types of etching processes within the same plasma processing tool 210. For example, the wafer 126A can be disposed under the gas shroud 110A, where the etching process 138 is performed on the wafer 126A. The wafer 126B can be disposed under the gas shroud 110B, where the etching process 139 is performed on the wafer 126B. The wafer 126C can be disposed under the gas shroud 110C, where the etching process 140 is performed on the wafer 126C. The wafer 126D can be disposed under the gas shroud 110D, where the etching process 141 is performed on the wafer 126D. Each of the etching process 138, the etching process 139, the etching process 140, and the etching process 141 may be different from the other etching processes. The etchants of each of the etching process 138, the etching process 139, the etching process 140, and the etching process 141 may be different from the etchants of the other etching processes. When a first wafer 126A under the gas shroud 110A is being subjected to a first etching process (e.g., one of the etching process 138, the etching process 139, the etching process 140, or the etching process 141), and a second adjacent wafer 126B under the gas shroud 110B is being subjected to another concurrent etching process (e.g., one of the etching process 138, the etching process 139, the etching process 140, or the etching process 141) in the plasma processing tool 210, sonic flow 119 can be used isolate and prevent etch by-products, unused radicals, and unreacted neutrals from the first etching process from coming into contact with the second wafer 126B, as well as isolate and prevent etch by-products, unused radicals, and unreacted neutrals from the second etching process from coming into contact with the first wafer 126A.

FIG. 4B illustrates a cross-sectional view of one of the gas shrouds 110A/110B/110C/110D that were shown in FIG. 4A. The example etching process described subsequently is explained in the context of an example etching process being used to etch the wafer 126A under the gas shroud 110A. However, the gas shroud 110B, the gas shroud 110C, and the gas shroud 110D may be similar to the gas shroud 110A, and the same description of the example etching process may apply to the etching of any of the wafer 126B, the wafer 126C, and the wafer 126D under the gas shroud 110B, the gas shroud 110C, and the gas shroud 110D, respectively, unless specified otherwise. FIG. 4B may illustrate a cross-sectional view of the gas shroud 110A along a line B-B shown in FIG. 4A.

The gas shroud 110A of the FIGS. 4A and 4B may differ from the gas shroud 110 described previously in FIGS. 1 through 3B in that the gas shroud 110A may have a larger width than a width of the gas shroud 110 described in FIGS. 1 through 3B. The gas shroud 110A is has a circular shape in a top-down view, and has a circular opening 123c on a topmost surface of the gas shroud 110A and a circular opening 123d at a bottommost surface of the gas shroud 110A. The opening 123d may have a larger diameter than the opening 123c, and the opening 123c may overlap and be connected to the opening 123d. The opening 123d of the gas shroud 110A also has a larger diameter than a diameter of the opening 123b of the gas shroud 110 described previously in FIGS. 1 through 3B. The opening 123d of the gas shroud 110A comprises a first space that is disposed between sidewalls of a base of the gas shroud 110A. The first region 128 comprises a combination of the first space of the opening 123d, and a second space disposed vertically below and overlapped by the opening 123d, the second space being between the opening 123 and a top surface of the susceptor 136. Because of the larger opening 123d, an entirety of the wafer 126A is encompassed within the first region 128.

The gas plenum 116 is used to create an inward sonic flow 119A in the first region 128, and to create an outward sonic flow 119B outside the first region 128. The inward sonic flow 119A is formed by distributing an inert gas uniformly from the gas plenum 116 to the first region 128 through a series of small orifices 121A (shown in FIG. 4B) in the base of the gas shroud 110. The orifices 121A may also be referred to subsequently as channels. In an embodiment, the orifices 121A are arranged in the form of a ring pattern in the base of the gas shroud 110, where the ring pattern is disposed around the opening 123d. The placement of the orifices 121A directs sonic flow 119A (e.g. in the form of jets of inert gas from each orifice 121A traveling at a speed equal to the speed of sound) towards a surface of the susceptor 136 at an angle, as well as towards the plasma plume 112 (e.g., inward sonic flow). For example, the orifices 121A are angled such that topmost portions of the sonic flow 119A may be further away form a vertical line C-C which passes through the center of the first region 128 and the nozzle 108 than bottommost portions of the sonic flow 119A that encounter a top surface of the susceptor 136. In this way, inward sonic flow 119A can be created that completely surrounds the plasma plume 112, and the wafer 126A in the first region 128.

The outward sonic flow 119B is formed by distributing the inert gas uniformly from the gas plenum 116 to a third region 135 through a series of small orifices 121B (shown in FIG. 4B) in the base of the gas shroud 110. The third region 135 are regions that are adjacent to and surround the first region 128, the third regions 135 comprising spaces between the base of the gas shroud 110 and top surfaces of the susceptor 136. The orifices 121B may also be referred to subsequently as channels. In an embodiment, the orifices 121B are arranged in the form of a ring pattern in the base of the gas shroud 110, where the ring pattern is disposed around the opening 123d and around the ring pattern of the orifices 121A. In an embodiment, the ring patterns of the orifices 121A and the orifices 121B are arranged concentrically, with the ring pattern of the orifices 121A having a smaller diameter than a diameter of the ring pattern of the orifices 121B. The placement of the orifices 121B directs sonic flow 119B (e.g. in the form of jets of inert gas from each orifice 121B traveling at a speed equal to the speed of sound) towards a surface of the susceptor 136 at an angle, as well as away from the plasma plume 112 (e.g., outward sonic flow). For example, the orifices 121B are angled such that topmost portions of the sonic flow 119B may be closer to the vertical line C-C which passes through the center of the first region 128 and the nozzle 108 than bottommost portions of the sonic flow 119B that encounter a top surface of the susceptor 136. In this way, outward sonic flow 119B can be created that completely surrounds the inward sonic flow 119A and the first region 128.

The inward sonic flow 119A completely surrounds the plasma plume 112 and the wafer 126A in the first region 128, and isolates them from the third regions 135 and other regions of the processing chamber of the plasma processing tool 210. The outward sonic flow 119B completely surrounds the first region 128, and further isolates the plasma plume 112 and the wafer 126A from other regions of the processing chamber of the plasma processing tool 210. The inward sonic flow 119A acts as a separatrix (also referred to as a boundary) between the first region 128 and the third regions 135. The outward sonic flow 119B also acts as a separatrix between the first region 128 and the third regions 135. For example, the first region 128 and the third regions 135 have distinct flows that are kept separate from each other by the sonic flows 119A and 119B. In this way the first region 128 may have and be maintained at a different pressure than the third regions 135.

Forming the sonic flow 119A that comprises jets of inert gas that flow into the first region 128 allows for maintaining a pressure differential between a pressure P4 in the first region 128 and a pressure P5 in the third regions 135. The sonic flow 119A that comprises jets of inert gas flowing into the first region 128 allows for maintaining the pressure P4 in the first region 128. Forming the sonic flow 119B that comprises jets of inert gas that flow into the third regions 135, and surround the first region 128 and the inward sonic flow 119A, allows for maintaining the pressure P5 in the third regions 135. In addition, forming the sonic flow 119A that flows into the first region 128 allows for maintaining a pressure differential between the pressure P4 in the first region 128 and a pressure in other regions of the processing chamber of the plasma processing tool 210. The pressure in the other regions of the processing chamber of the plasma processing tool 210 may be equal to a pressure P6. The pressure P6 may be greater than the pressure P4 and the pressure P5. In an embodiment, the pressure P4 in the first region 128 may be in a range from 0.1 torr to 5.0 torr. In an embodiment, the pressure P5 in the third regions 135 may be in a range from 0.1 torr to 5.0 torr. In an embodiment, the pressure P6 in the other regions of the processing chamber of the plasma processing tool 210 may be in a range from 0.1 torr to 5.0 torr.

Advantages can be achieved by forming the inward sonic flow 119A in the first region 128 that completely surrounds the plasma plume 112 and the wafer 126A, and by forming the outward sonic flow 119B in the third regions 135 that surround the inward sonic flow 119A and the first region 128. Each of the inward sonic flow 119A and the outward sonic flow 119B form a separatrix to isolate the plasma plume 112, the wafer 126A, and the first region 128 from the second regions 133. These separatrices prevent etch by-products, unused radicals, and unreacted neutrals that result from the etching process being performed on the wafer 126A in the first region 128 from traveling or diffusing to the second regions 133 and other regions of the processing chamber of the plasma processing tool 210. They therefore do not come into contact with surfaces of the other adjacent wafers 126 (e.g., the wafer 126B, the wafer 126C, and the wafer 126D) in the processing chamber of the plasma processing tool 210. This results in reduced etch damage from the unused etch radicals, and reduced contamination from the etch by-products and the unreacted neutrals to the other wafers 126 (e.g., the wafer 126B, the wafer 126C, and the wafer 126D) in the processing chamber. Additionally, etch by-products, unused radicals, and unreacted neutrals that result from etching processes being performed on the other wafers 126 (e.g., the wafer 126B, the wafer 126C, and the wafer 126D) are prevented from traveling to or diffusing into the first region 128. This also allows for different wafers 126 to be subjected to different etching processes (e.g., the etching process 138, the etching process 139, the etching process 140, and the etching process 141) concurrently in the same processing chamber, without etch by-products, unused radicals, and unreacted neutrals from one of the etching processes adversely affecting adjacent wafers 126. It should be noted that although the advantages described above relate to the use of the plasma processing tool 210 being used to perform an etching process, the plasma processing tool 210 can also be used to perform deposition processes, or a cyclic combination of etching and deposition processes, where the inward sonic flow 119A and the outward sonic flow 119B perform the same function to form a separatrix to isolate the plasma plume 112, the wafer 126A, and the first region 128 from the second regions 133.

The plasma plume 112 may have a lateral width W2, where the lateral width W2 is a width between outermost points of the plasma plume 112 that are in physical contact with a top surface of the wafer 126A. The lateral width W2 is dependent on the pressure P4 in the first region 128, such that a higher pressure P4 results in a decrease in the lateral width W2 of the plasma plume 112. A lower pressure P4 results in an increase in the lateral width W2 of the plasma plume 112. Design selection of the gas shroud 110A can therefore be used to maintain an appropriate pressure P4 within the first region 128, in order to achieve the plasma plume 112 with the desired lateral width W2. In an embodiment, the lateral width W2 of the plasma plume 112 may be in a range from 2.0 mm to 350.0 mm.

The pressure P4 in the first region 128 can be maintained by using the sonic flow 119A flowing into the first region 128. The flowrate of the sonic flow 119A may influence the pressure P4 that can be maintained. For example, a gas shroud 110A having more orifices 121A would have a higher flowrate of the inert gas flowing into the first region 128, and hence a higher pressure P4 could be maintained. A gas shroud 110 having fewer orifices 121A would have a lower flowrate of the inert gas flowing into the first region 128, and hence it would only be possible to maintain a lower pressure P4.

Advantages can be achieved by using the gas shroud 110A to create the sonic flow 119A in the first region 128 in order to maintain the pressure P4 in the first region 128. For example, using the sonic flow 119A to maintain a higher pressure P4 in the first region 128 would result in a decrease in the lateral width W2 of the plasma plume 112, while using the sonic flow 119A to maintain a lower pressure P4 in the first region 128 would result in an increase in the lateral width W2 of the plasma plume 112. Being able to control the lateral width W2 of the plasma plume 112 allows for better etch control, improved focusing of the plasma plume 112, and better etch spot size control, which allows for high-resolution etching and results in better uniformity across the surface of the wafer 126. In addition, it is more convenient and easier to maintain the pressure P4 in the first region 128 during plasma processing, than to adjust the pressure in the entire processing chamber of the plasma processing tool 210. This is because a volume of the first region 128 is much smaller than a volume of the processing chamber of the plasma processing tool 210.

The vacuum pump 120 maintains the first section 129, the second section 130 and the third section 131 (shown previously in FIG. 2) of the gas shroud 110A at a lower pressure than the first region 128. As a result, etch by-products, unused radicals, unreacted neutrals from the etching process, and the inert gas used to create the sonic flow 119A travel from the higher pressure first region 128 to the lower pressure first section 129, the second section 130, and the third section 131. The etch by-products, the unused radicals, unreacted neutrals, and the inert gas used to create the sonic flow 119A are then removed up through the gas shroud 110A using the flow path 132 and out through a gas outlet of the gas shroud 110A that is connected to the vacuum pump 120. In an embodiment, more than one gas outlet and one or more vacuum pumps 120 may be connected to the gas shroud 110A to allow for different pumping capacities. Advantages can be achieved by using the sonic flow 119A to maintain the pressure P4 in the first region 128 to be higher than the pressure in the first section 129, the second section 130 and the third section 131 of the gas shroud 110A. This allows the etch by-products, the unused radicals, and the unreacted neutrals that result from the etching process to be removed up through the gas shroud 110A and out through the gas outlet of the gas shroud 110A that is connected to the vacuum pump 120. As a result, the etch by-products, the unused radicals, and the unreacted neutrals have reduced contact with surfaces of the other wafer 126 (e.g., the wafer 126B, the wafer 126C, and the wafer 126D) in the processing chamber. This results in reduced etch damage from the unused etch radicals, and reduced contamination from the etch by-products and the unreacted neutrals to the other wafers 126 in the processing chamber of the plasma processing tool 210.

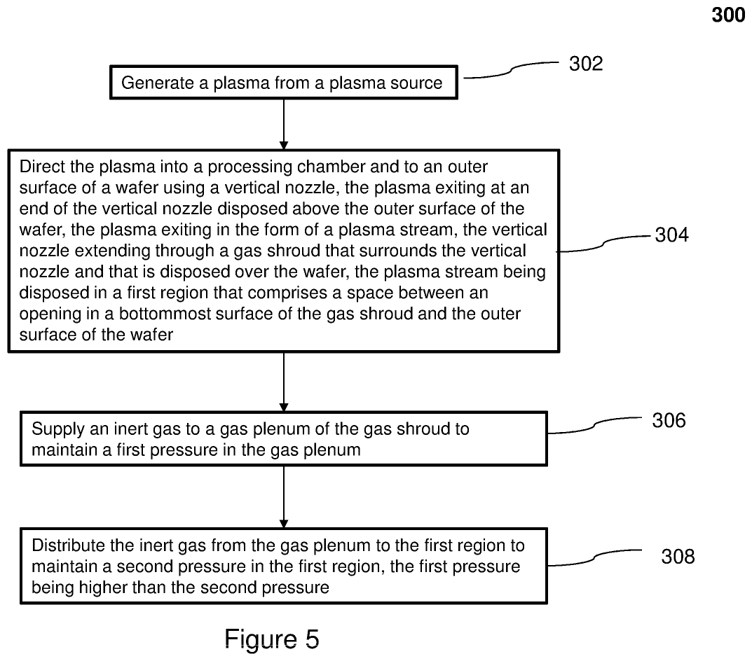

FIG. 5 illustrates a flow chart 300 that comprises a method of generating a plasma from a plasma source (box 302), and directing the plasma into a processing chamber and to an outer surface of a wafer using a vertical nozzle (box 304). The method of plasma processing further includes supplying (box 306) an inert gas to a gas plenum of the gas shroud to maintain a first pressure in the gas plenum, and distributing (box 308) the inert gas from the gas plenum to the first region to maintain a second pressure in the first region, the first pressure being higher than the second pressure. These method steps can be implemented using the embodiments described previously in detail in FIGS. 1 through 4B.

Although embodiments of the present disclosure and its advantages have been described in detail, it should be understood that various changes, substitutions and alterations can be made herein without departing from the spirit and scope of the disclosure as defined by the appended claims.

Example embodiments of the invention are described below. Other embodiments can also be understood from the entirety of the specification as well as the claims filed herein.

Example 1. A plasma processing apparatus includes a plasma generation source, a nozzle in a plasma chamber, the nozzle being able to direct plasma from the plasma generation source to a wafer that is to be processed. The plasma has the form of a plasma stream at an exit of the nozzle. The plasma processing apparatus also includes a gas shroud disposed in the plasma chamber and over the wafer, the gas shroud surrounding the nozzle. The gas shroud includes a first circular opening in a top surface of the gas shroud, a second circular opening in a bottommost surface of the gas shroud, the nozzle being disposed in the first circular opening and the second circular opening. The gas shroud also includes a gas plenum configured to be maintained at a first pressure, a first region between the second circular opening and a top surface of the wafer being configured to be maintained at a second pressure, the first pressure and the second pressure being different.

Example 2. The plasma processing apparatus of example 1, where the first pressure is larger than the second pressure.

Example 3. The plasma processing apparatus of one of examples 1 or 2, where the first pressure is in a range from 1.0 torr to 50.0 torr, and the second pressure is in a range from 0.1 torr to 5.0 torr.

Example 4. The plasma processing apparatus of one of examples 1 to 3, further including orifices that directly connect and allow flow of gas between the gas plenum and the first region.

Example 5. The plasma processing apparatus of example 4, where the orifices are arranged in the form of a ring pattern, the ring pattern being disposed around the second circular opening.

Example 6. The plasma processing apparatus of one of examples 4 to 5, where the flow of gas between the gas plenum and the first region through the orifices is in the form of jets of the gas, and where the jets of the gas surround the plasma stream.

Example 7. The plasma processing apparatus of example 6, where the jets of the gas travel at a speed that is equal to the speed of sound.

Example 8. The plasma processing apparatus of one of examples 4 to 7, where each of the orifices has a diameter that is in a range from 0.3 mm to 2.0 mm.

Example 9. The plasma processing apparatus of one of examples 1 to 8, where the plasma stream has a lateral width that is in a range from 2 mm to 20 mm, the lateral width being a width between outermost points of the plasma stream that are in physical contact with the top surface of the wafer.

Example 10. A method of plasma processing includes generating a plasma from a plasma source, and directing the plasma into a processing chamber and to an outer surface of a wafer using a vertical nozzle. The plasma exits at an end of the vertical nozzle disposed above the outer surface of the wafer, and the plasma exits in the form of a plasma stream. The vertical nozzle extends through a gas shroud that surrounds the vertical nozzle and that is disposed over the wafer. The plasma stream is disposed in a first region that comprises a space between an opening in a bottommost surface of the gas shroud and the outer surface of the wafer. The method of plasma processing further includes supplying an inert gas to a gas plenum of the gas shroud to maintain a first pressure in the gas plenum, and distributing the inert gas from the gas plenum to the first region to maintain a second pressure in the first region, the first pressure being higher than the second pressure.

Example 11. The method of example 10, where second regions that are adjacent to and that surround the first region have a third pressure, the third pressure being different from the first pressure and the second pressure.

Example 12. The method of one of examples 10 or 11, where distributing the inert gas from the gas plenum to the first region includes flowing jets of the inert gas through channels disposed in a base of the gas shroud.

Example 13. The method of example 12, where the jets of the inert gas travel at a speed equal to the speed of sound.

Example 14. The method of one of examples 12 to 13, where topmost portions of the jets of the inert gas are further away form a vertical line which passes through a center of the first region and the vertical nozzle than bottommost portions of the jets of the inert gas that encounter the outer surface of the wafer.

Example 15. The method of one of examples 10 to 14, where the first region encompasses an entirety of the wafer.

Example 16. An apparatus includes a radical source, a nozzle configured to deliver radicals from the radical source into a processing chamber, and a gas shroud disposed over a wafer to be processed in the processing chamber. The gas shroud includes a first opening in a topmost surface of the gas shroud, and a second opening in a bottommost surface of the gas shroud. A first region is disposed between the second opening and a top surface of the wafer. The gas shroud also includes a gas plenum, and first orifices arranged in the form of a ring pattern around the second opening. The first orifices act as a conduit for gas flow between the gas plenum and the first region, and an exit of the nozzle is disposed in the first region above the wafer. The nozzle extends through the first opening, the second opening, and the gas shroud.

Example 17. The apparatus of example 16, where the gas shroud further includes a gas inlet, an inert gas being supplied to the gas plenum through the gas inlet to maintain the gas plenum at a first pressure, and a gas outlet connected to a vacuum pump to remove unused radicals and contaminants from the gas shroud.

Example 18. The apparatus of example 17, where the first region is maintained at a second pressure, the first pressure being higher than the second pressure.

Example 19. The apparatus of one of examples 16 to 18, where the gas flow in the first orifices between the gas plenum and the first region is in the form of first jets of gas, and where the first jets of gas travel at a speed equal to the speed of sound.

Example 20. The apparatus of one of examples 18 to 19, further includes second orifices arranged in the form of a ring pattern around the first orifices, the second orifices acting as a conduit for gas flow between the gas plenum and a second region, wherein the second region surrounds and is adjacent to the first region, wherein the gas flow in the second orifices between the gas plenum and the second region is in the form of second jets of gas, wherein the second jets of gas travel at a speed equal to the speed of sound, wherein the second jets of gas travel in a direction that leads away from the nozzle, and wherein the second region has a pressure that is different from the first pressure and the second pressure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A plasma processing apparatus comprising:
a plasma generation source;
a nozzle in a plasma chamber, the nozzle being able to direct plasma from the plasma generation source to a wafer that is to be processed, the plasma having the form of a plasma stream at an exit of the nozzle;
a gas shroud disposed in the plasma chamber and over the wafer, the gas shroud surrounding the nozzle, the gas shroud comprising:
a first circular opening in a top surface of the gas shroud;
a second circular opening in a bottommost surface of the gas shroud, the nozzle being disposed in the first circular opening and the second circular opening; and
a gas plenum configured to be maintained at a first pressure, a first region between the second circular opening and a top surface of the wafer being configured to be maintained at a second pressure, the first pressure and the second pressure being different.

2. The plasma processing apparatus of claim 1, wherein the first pressure is larger than the second pressure.

3. The plasma processing apparatus of claim 1, wherein the first pressure is in a range from 1.0 torr to 50.0 torr, and the second pressure is in a range from 0.1 torr to 5.0 torr.

4. The plasma processing apparatus of claim 1, further comprising orifices that directly connect and allow flow of gas between the gas plenum and the first region.

5. The plasma processing apparatus of claim 4, wherein the orifices are arranged in the form of a ring pattern, the ring pattern being disposed around the second circular opening.

6. The plasma processing apparatus of claim 5, wherein the flow of gas between the gas plenum and the first region through the orifices is in the form of jets of the gas, and wherein the jets of the gas surround the plasma stream.

7. The plasma processing apparatus of claim 6, wherein the jets of the gas travel at a speed that is equal to the speed of sound.

8. The plasma processing apparatus of claim 7, wherein each of the orifices has a diameter that is in a range from 0.3 mm to 2.0 mm.

9. The plasma processing apparatus of claim 1, wherein the plasma stream has a lateral width that is in a range from 2 mm to 20 mm, the lateral width being a width between outermost points of the plasma stream that are in physical contact with the top surface of the wafer.

10. A method of plasma processing comprising:
generating a plasma from a plasma source;
directing the plasma into a processing chamber and to an outer surface of a wafer using a vertical nozzle, the plasma exiting at an end of the vertical nozzle disposed above the outer surface of the wafer, the plasma exiting in the form of a plasma stream, the vertical nozzle extending through a gas shroud that surrounds the vertical nozzle and that is disposed over the wafer, the plasma stream being disposed in a first region that comprises a space between an opening in a bottommost surface of the gas shroud and the outer surface of the wafer;
supplying an inert gas to a gas plenum of the gas shroud to maintain a first pressure in the gas plenum; and
distributing the inert gas from the gas plenum to the first region to maintain a second pressure in the first region, the first pressure being higher than the second pressure.

11. The method of claim 10, wherein second regions that are adjacent to and that surround the first region have a third pressure, the third pressure being different from the first pressure and the second pressure.

12. The method of claim 10, wherein distributing the inert gas from the gas plenum to the first region comprises flowing jets of the inert gas through channels disposed in a base of the gas shroud.

13. The method of claim 12, wherein the jets of the inert gas travel at a speed equal to the speed of sound.

14. The method of claim 13, wherein topmost portions of the jets of the inert gas are further away form a vertical line which passes through a center of the first region and the vertical nozzle than bottommost portions of the jets of the inert gas that encounter the outer surface of the wafer.

15. The method of claim 10, wherein the first region encompasses an entirety of the wafer.

16. An apparatus comprising:
a radical source;
a nozzle configured to deliver radicals from the radical source into a processing chamber;
a gas shroud disposed over a wafer to be processed in the processing chamber, the gas shroud comprising:
a first opening in a topmost surface of the gas shroud;
a second opening in a bottommost surface of the gas shroud, a first region being disposed between the second opening and a top surface of the wafer;
a gas plenum; and
first orifices arranged in the form of a ring pattern around the second opening, the first orifices acting as a conduit for gas flow between the gas plenum and the first region, an exit of the nozzle being disposed in the first region and being above the wafer, the nozzle extending through the first opening, the second opening, and the gas shroud.

17. The apparatus of claim 16, wherein the gas shroud further comprises a gas inlet, an inert gas being supplied to the gas plenum through the gas inlet to maintain the gas plenum at a first pressure, and a gas outlet connected to a vacuum pump to remove unused radicals and contaminants from the gas shroud.

18. The apparatus of claim 17, wherein the first region is maintained at a second pressure, the first pressure being higher than the second pressure.

19. The apparatus of claim 18, wherein the gas flow in the first orifices between the gas plenum and the first region is in the form of first jets of gas, and wherein the first jets of gas travel at a speed equal to the speed of sound.

20. The apparatus of claim 19, further comprising:
second orifices arranged in the form of a ring pattern around the first orifices, the second orifices acting as a conduit for gas flow between the gas plenum and a second region, wherein the second region surrounds and is adjacent to the first region, wherein the gas flow in the second orifices between the gas plenum and the second region is in the form of second jets of gas, wherein the second jets of gas travel at a speed equal to the speed of sound, wherein the second jets of gas travel in a direction that leads away from the nozzle, and wherein the second region has a pressure that is different from the first pressure and the second pressure.
